(19) United States
(12) Patent Application Publication
(10) Pub. No.: US 2014/0252313 A1
(43) Pub. Date: Sep. 11, 2014

(54) NANOLENS ARRAYS IN NANOPILLAR OPTOELECTRONIC DEVICES

(71) Applicant: THE REGENTS OF THE UNIVERSITY OF CALIFORNIA, Oakland, CA (US)

(72) Inventors: Giacomo Mariani, Los Angeles, CA (US); Diana L. Huffaker, Camarillo, CA (US)

(21) Appl. No.: 14/199,647

(22) Filed: Mar. 6, 2014

Related U.S. Application Data
(60) Provisional application No. 61/773,747, filed on Mar. 6, 2013.

(51) Int. Cl. H01L 31/0352; H01L 31/18

(52) U.S. Cl. CPC H01L 31/035236; H01L 31/1884
USPC 257/21; 438/71

(57) ABSTRACT

An optoelectronic device includes: (1) a top transparent electrode; (2) a bottom electrode spaced apart from the top transparent electrode; and (3) nanopillars arranged between the top transparent electrode and the bottom electrode such that each of the nanopillars includes a top end electrically connected to the top transparent electrode and a bottom end electrically connected to the bottom electrode. The top transparent electrode is shaped to provide optical elements each arranged to couple light into or out of a respective one of the nanopillars.

### CROSS-REFERENCE TO RELATED APPLICATION

This application claims the benefit of U.S. Provisional Application Ser. No. 61/773,747, filed on Mar. 6, 2013, the disclosure of which is incorporated herein by reference in its entirety.

### STATEMENT REGARDING FEDERALLY SPONSORED RESEARCH OR DEVELOPMENT

This invention was made with Government support under DGE0903720, DMR1007051, and ECCS0824273, awarded by the National Science Foundation, and N00244-09-1-0091, awarded by the Department of Defense. The Government has certain rights in the invention.

### FIELD OF THE INVENTION

This disclosure generally relates to optoelectronic devices and, more particularly, to nanopillar-based and nanowire-based optoelectronic devices including nanolens arrays.

### BACKGROUND

Semiconductor nanostructures have recently fueled numerous optoelectronic fields. Arrays of nanopillars (NPs) have been examined by the photovoltaic (PV) community as highly efficient solar absorbers, with potential material and cost reductions compared to planar architectures. Despite modeled predictions, experimental efficiencies are constrained by surface recombination and poor light management, once integrated in a practical PV device.

It is against this background that a need arose to develop the nanopillar-based optoelectronic devices and related methods described herein.

### SUMMARY

One aspect of this disclosure relates to an optoelectronic device. In some embodiments, the optoelectronic device includes: (1) a top transparent electrode; (2) a bottom electrode spaced apart from the top transparent electrode; and (3) nanopillars arranged between the top transparent electrode and the bottom electrode such that each of the nanopillars includes a top end electrically connected to the top transparent electrode and a bottom end electrically connected to the bottom electrode. The top transparent electrode is shaped to provide optical elements each arranged to couple light into or out of a respective one of the nanopillars.

Another aspect of this disclosure relates to a fabrication method of an optoelectronic device. In some embodiments, the fabrication method includes: (1) providing a substrate and nanopillars arranged in an array and each extending from the substrate; (2) applying an insulating material over the array of the nanopillars; (3) performing an etch-back of the insulating material to expose tips of the array of the nanopillars; and (4) depositing a layer of a transparent conducting oxide to conformally cover the exposed tips of the array of the nanopillars. The layer of the transparent conducting oxide includes convex regions arranged in a corresponding array that is aligned with the array of the nanopillars.

Other aspects and embodiments of this disclosure are also contemplated. The foregoing summary and the following detailed description are not meant to restrict this disclosure to any particular embodiment but are merely meant to describe some embodiments of this disclosure.

### BRIEF DESCRIPTION OF THE DRAWINGS

For a better understanding of the nature and objects of some embodiments of this disclosure, reference should be made to the following detailed description taken in conjunction with the accompanying drawings.

FIG. 1A, FIG. 1B, FIG. 1C, and FIG. 1D: A sequence of operations of a fabrication method of a NP-based PV device, according to an embodiment of this disclosure.

FIG. 2: A top image of an array of nanolenses conformally covering and aligned with an array of NPs, according to an embodiment of this disclosure.

FIG. 3(a), FIG. 3(b), and FIG. 3(c): Tuning of a morphology of a top transparent electrode by controlling an extent of exposure of a NP, according to an embodiment of this disclosure.

FIG. 4. (a) Three-dimensional illustration of a designed and fabricated NP core-multishell structure: a p-i-n radial junction is wrapped in a InGaP shell to lessen surface-state-induced surface recombination. (b) Typical scanning electron microscopy (SEM) image of vertically aligned NP arrays. (c) Benzocyclobutene (BCB) planarization layer and etch-back operation to partly expose back the NPs.

FIG. 5. (a) Top-view SEM image of a NP array with four area-dependent transparent contacts photolithographically specified on top. (b) SEM micrograph of a zoomed-in boundary in (a) to demonstrate the difference between bare NP tips and conformal dome-shaped morphology once indium tin oxide (ITO) is deposited. (c) Apparent photocurrent/active area characteristics for NP solar cells with increasing area. An extrapolated substrate photocurrent from the linear regression (R²=0.99) is about 3.2 μA. (d) Actual photocurrent density/active area plot showing an about 18.9 mA/cm² current density irrespective of the device area.

FIG. 6. (a) Measured current density-voltage (J-V) characteristics of GaAs p-i-n NP-array solar cells under AM1.5G. (b) Calculated J-V curve by way of finite-difference time-domain (FDTD) simulations.

FIG. 7. External quantum efficiency measurements (circular dots) of solar cells from 400 nm to 950 nm. FDTD simulations are carried out to analyze the impact of a planar (triangles) and a dome-shaped ITO layer (squares) on the final optical coupling performance. The latter shows a good fidelity compared to the measured data.

FIG. 8. (a) Optical generation profiles calculated by FDTD for wavelengths at 405 nm, 505 nm, 600 nm, 700 nm, 808 nm, and 892 nm. Contrast map is common to all six profiles. Through the dome-shaped ITO, light is coupled into the NP array, penetrating deeper into the semiconductor material at longer wavelengths. (b) Integrated-AM1.5G optical power flux within the periodic structure. Each ITO dome acts as a subwavelength nanolens, concentrating the optical power in the active NP region.

FIG. 9. Comparison of simulated (FDTD) J-V characteristics under AM1.5G for a periodic NP array with and without dome-shaped ITO layer.

FIG. 10. Schematic of different pathways for area-dependent photocurrent measurements: photocurrent contributions from contacted and non-contacted NPs and substrate are outlined.

FIG. 11. (a) SEM micrograph of a shallow BCB etch-back to barely expose NP tips. (b) SEM micrograph of ITO sputtering: the samples are planarized without dome formation. (c) Dome formation on different NP tip heights: the process is sensitive to the profile of NP tip exposed subsequent to etch-back.

FIG. 12. Experimental comparison of core-shell NP arrays processed with different ITO layer morphologies, demonstrating broadband light coupling arising from dome-shaped transparent electrode.

### DETAILED DESCRIPTION

### Definitions

The following definitions apply to some of the aspects described with regard to some embodiments of this disclosure. These definitions may likewise be expanded upon herein.

As used herein, the singular terms “a,” “an,” and “the” include plural referents unless the context clearly dictates otherwise. Thus, for example, reference to an object can include multiple objects unless the context clearly dictates otherwise.

As used herein, the term “set” refers to a collection of one or more objects. Thus, for example, a set of objects can include a single object or multiple objects. Objects of a set can also be referred to as members of the set. Objects of a set can be the same or different. In some instances, objects of a set can share one or more common properties.

As used herein, the terms “substantially,” “substantial,” and “about” are used to describe and account for small variations. When used in conjunction with an event or circumstance, the terms can refer to instances in which the event or circumstance occurs precisely as well as instances in which the event or circumstance occurs to a close approximation. For example, with respect to a numerical value, the terms can refer to less than or equal to ±10% of the value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

As used herein, the terms “optional” and “optionally” mean that the subsequently described event or circumstance may or may not occur and that the description includes instances where the event or circumstance occurs and instances in which it does not.

As used herein, the terms “connect,” “connected,” and “connection” refer to an operational coupling or linking. Connected objects can be directly coupled to one another or can be indirectly coupled to one another, such as via another set of objects.

As used herein, relative terms, such as “inner,” “interior,” “outer,” “exterior,” “top,” “bottom,” “front,” “rear,” “back,” “upper,” “upwardly,” “lower,” “downwardly,” “vertical,” “vertically,” “lateral,” “laterally,” “above,” and “below,” refer to an orientation of a set of objects with respect to one another, such as in accordance with the drawings, but do not require a particular orientation of those objects during manufacturing or use.

As used herein, the term “nanometer range” or “nm range” refers to a range of dimensions from about 1 nanometer (nm) to about 1 micrometer (μm). The nm range includes the “lower nm range,” which refers to a range of dimensions from about 1 nm to about 10 nm, the “middle nm range,” which refers to a range of dimensions from about 10 nm to about 100 nm, and the “upper nm range,” which refers to a range of dimensions from about 100 nm to about 1 μm.

As used herein, the term “micrometer range” or “μm range” refers to a range of dimensions from about 1 μm to about 1 millimeter (mm). The μm range includes the “lower μm range,” which refers to a range of dimensions from about 1 μm to about 10 μm, the “middle μm range,” which refers to a range of dimensions from about 10 μm to about 100 μm, and the “upper μm range,” which refers to a range of dimensions from about 100 μm to about 1 mm.

As used herein, the term “ultraviolet range” refers to a range of wavelengths from about 5 nm to about 400 nm.

As used herein, the term “visible range” refers to a range of wavelengths from about 400 nm to about 700 nm.

As used herein, the term “infrared range” refers to a range of wavelengths from about 700 nm to about 2 mm.

As used herein, the term “aspect ratio” refers to a ratio of a largest dimension or extent of an object and an average of remaining dimensions or extents of the object, where the remaining dimensions can be substantially orthogonal with respect to one another and with respect to the largest dimension. In some instances, remaining dimensions of an object can be substantially the same, and an average of the remaining dimensions can substantially correspond to either of the remaining dimensions. For example, an aspect ratio of a cylinder refers to a ratio of a length of the cylinder and a cross-sectional diameter of the cylinder. As another example, an aspect ratio of a spheroid refers to a ratio of a major axis of the spheroid and a minor axis of the spheroid.

As used herein, the term “nanostructure” refers to an object that has at least one dimension in the nm range. A nanostructure can have any of a wide variety of shapes, and can be formed of a wide variety of materials. Examples of nanostructures include nanopillars and nanotubes, among other nanostructures.

As used herein, the term “nanopillar” or “NP” refers to an elongated, nanostructure that is substantially solid. A nanopillar also can be referred to as a nanowire (NW). Typically, a nanopillar has a lateral dimension (e.g., a cross-sectional dimension in the form of a width, a diameter, or a width or diameter that represents an average across orthogonal directions) in the nm range, a longitudinal dimension (e.g., a height or a length) in the μm range, and an aspect ratio that is about 2 or greater.

As used herein, the term “nanotube” refers to an elongated, hollow, nanostructure. Typically, a nanotube has a lateral dimension (e.g., a cross-sectional dimension in the form of a width, an outer diameter, or a width or outer diameter that represents an average across orthogonal directions) in the nm range, a longitudinal dimension (e.g., a height or a length) in the μm range, and an aspect ratio that is about 2 or greater.

As used herein, the term “microstructure” refers to an object that has at least one dimension in the μm range. Typically, each dimension of a microstructure is in the μm range or beyond the μm range. A microstructure can have any of a wide variety of shapes, and can be formed of a wide variety of materials. Examples of microstructures include microwires and microtubes, among other microstructures.

As used herein, the term “micropillar” refers to an elongated, microstructure that is substantially solid. A micropillar also can be referred to as a microwire. Typically, a micropillar has a lateral dimension (e.g., a cross-sectional dimension in the form of a width, a diameter, or a width or diameter that represents an average across orthogonal directions) in the μm range and an aspect ratio that is about 2 or greater.

As used herein, the term “microtube” refers to an elongated, hollow, microstructure. Typically, a microtube has a lateral dimension (e.g., a cross-sectional dimension in the form of a width, an outer diameter, or a width or outer diameter that represents an average across orthogonal directions) in the μm range and an aspect ratio that is about 2 or greater.

Additionally, dimensions, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified. For example, a range of about 1 to about 200 should be understood to include the explicitly recited limits of about 1 and about 200, but also to include individual values such as about 2, about 3, and about 4, and sub-ranges such as about 10 to about 50, about 20 to about 100, and so forth.

### Nanopillar-Based Optoelectronic Devices

Nanostructures, such as NPs, have promoted advances in several optoelectronic fields including optical modulators, light-emitting devices, photodetectors, and solar cells. Semiconductor NPs have exhibited enhanced (1) optical properties in terms of tunability and enhanced absorption, and (2) electrical properties of radial junctions in terms of charge separation that is more tolerant to material defects. For these reasons, considerable effort is being devoted to exploiting NPs as next-generation PV devices. Nanometer-sized footprint of NPs allows for dissimilar material integration, where lattice matching requirements due to strain accommodation are relaxed. For instance, silicon NPs can be grown on a wide variety of substrates, and direct-bandgap III-V semiconductor NPs can be synthesized on inexpensive platforms. In addition, the NPs can be released from a native substrate and integrated into flexible, low cost PV devices.

To analyze the interaction of a normally-incident optical field with semiconducting NPs, single-NW devices are generally fabricated by dispersing the nanostructures onto an oxide-coated silicon substrate. Such analysis demonstrated optical absorption engineering through leaky-mode resonances arising from a subwavelength confinement of light. Furthermore, polarization-resolved external quantum efficiency (EQE) spectra exhibited diameter-dependent peaks, tunable by a morphological design of the nanostructures. However, the strength of NP PV devices manifests when arrays of three-dimensional, substantially vertically-aligned NPs are considered collectively: light trapping increases the effective optical path length of incoming photons, exceeding the 2n² Lambertian threshold under certain conditions. This effect can enhance considerably the absorption of solar radiation with respect to planar architectures. The adoption of a substantially periodic, position-controlled NP array can be employed to tune its corresponding absorption properties. Specific values, such as diameter (D) and pitch (P), can affect the propagation of light in the subwavelength regime, where a sequence of high refractive index III-V semiconductor and air can be formalized by the effective medium approximation theory.

Direct-bandgap III-V semiconductors can benefit from extremely high optical absorption coefficients, resulting into about 100 times (or more) thinner material to absorb about 90% of above-bandgap solar photons compared to silicon. Furthermore, analysis of several III-V semiconductors, including indium phosphide (InP), indium arsenide (InAs), and gallium arsenide (GaAs) NP arrays, indicates wideband absorption values approaching unity. Nonetheless, photon-to-electron power conversion efficiencies (PCEs) of other NP-array PV devices based on this class of materials remain at low values of 3.37% or under, under air mass 1.5 global (AM1.5G). Hence, it is desirable to correlate optical properties of a fully-integrated device structure (that will interface to an external optical field) with electrical properties of the device measured at its terminals.

Some embodiments of this disclosure provide a method to fabricate optically concentrating nanolenses on NP arrays, for use or inclusion in solar cells and other optoelectronic devices. The fabrication method takes advantage of sputtering techniques of transparent conducting oxides (TCOs) used in optoelectronics. In some embodiments, the fabrication method yields a desirable dome-shaped morphology of a TCO layer on top of an active NP array, and this dome-shaped TCO layer functions both as an electrical contact (namely as a transparent electrode) and an optical concentrator of subwavelength dimensions. The effect can be broadband with additional spectral resonances with respect to planar contacts. In combination with improved light management attained though the use of nanolenses, a passivating window layer is included in NP arrays to mitigate against surface recombination, thereby yielding a practical optoelectronic device exhibiting high performance.

Some embodiments of this disclosure integrate dome-shaped TCO top transparent electrodes into NP-based PV devices to both function as optical concentrators and electrical contacts. Each dome-shaped region (or nanodome) is substantially self-aligned with a corresponding NP, with no requirement for dedicated patterning techniques. Each TCO nanodome acts as a subwavelength lens (or as a refractive or focusing optical element) that concentrates and augments a photon flux within an active NP volume. In some embodiments, sputtering techniques are used to form convex-shaped TCO nanolenses on top of NP arrays, although concave and other shapes of nanolenses are also contemplated. Optical features, such as focus and curvature of the nanolenses, for example, can be tuned by varying an extent of NPs exposed during a sputtering deposition. The focusing effect is broadband with additional optical resonance peaks in the case of substantially periodically ordered lens and NP arrays.

Suitable TCOs include metal oxides that are doped or undoped. TCOs can be crystalline, polycrystalline, or amorphous. Examples include indium tin oxide (or ITO or tin-doped indium oxide, e.g., In₂O₃:Sn), fluorine-doped tin oxide (e.g., SnO₂:F or FTO), antimony-doped tin oxide (e.g., SnO₂:Sb), aluminum-doped zinc oxide (e.g., ZnO:Al or AZO), gallium-doped zinc oxide (e.g., ZnO:Ga), boron-doped zinc oxide (e.g., ZnO:B), indium-doped zinc oxide (e.g., ZnO:In), cadmium oxide (doped or undoped), zinc-doped aluminum oxide, cadmium tin oxides (doped or undoped, e.g., Cd₂SnO₄), and mixtures or combinations thereof. Transparent conducting chalcogenides can be used in place of, or in combination with, TCOs, such as cadmium sulfide (doped or undoped) and zinc sulfide (doped or undoped).

When formed into layers or films, such as in the form of transparent electrodes, TCOs and transparent conducting chalcogenides can have a light transmittance of at least about 50%, such as at least about 60%, at least about 70%, at least about 80%, at least about 85%, or at least about 90%, and up to about 95%, up to about 98%, or more. It will be understood that transmittance can be measured at a particular wavelength of interest or over a particular range of wavelengths of interest, such as transmittance over a range of wavelengths from about 400 nm to about 950 nm, transmittance over a range of wavelengths from about 400 nm to about 900 nm, transmittance at a particular wavelength or over a particular range of wavelengths in the visible range, a solar-flux weighted transmittance, transmittance at a particular wavelength or over a particular range of wavelengths in the infrared range, and transmittance at a particular wavelength or over a particular range of wavelengths in the ultraviolet range. Also, TCOs and transparent conducting chalcogenides can have a sheet resistance of up to about 1,000 Ω/sq, such as up to about 500 Ω/sq, up to about 400 Ω/sq, up to about 300 Ω/sq, up to about 200 Ω/sq, or up to about 100 Ω/sq, and down to about 50 Ω/sq, down to about 20 Ω/sq, or less.

Applications can include, for example, optical modulators, light-emitting devices or other photoemission devices, photodetectors, and solar cells. For example, some embodiments of this disclosure can be implemented in NP-based solar cells in order to achieve high photocurrents originating from an intense optical field from subwavelength concentration. Applications and implementations of other optoelectronic devices can be provided by adjusting or tuning optical concentrators to permit either, or both, inward light coupling (e.g., photodetectors and PV devices) and outward light coupling (e.g., light-emitting devices) with an external environment. The optoelectronic functionality also can be applied to arrays of other types of nanostructures as well as arrays of microstructures, such as to enhance photodetection response or photon-to-electron conversion in the visible spectrum or other ranges of wavelength.

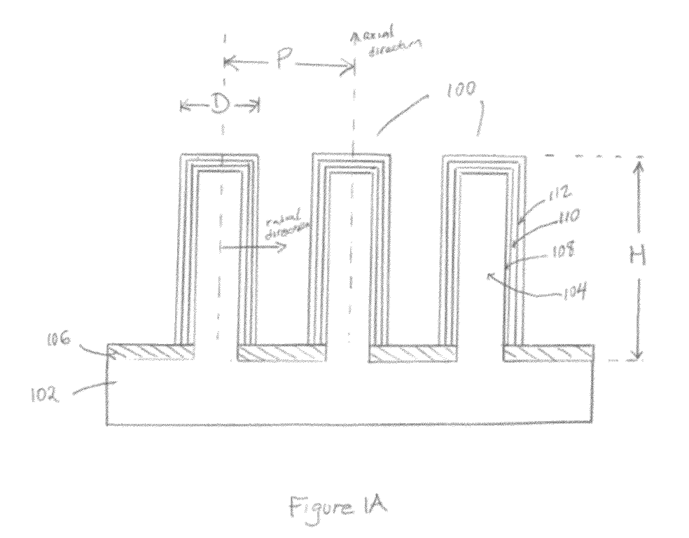

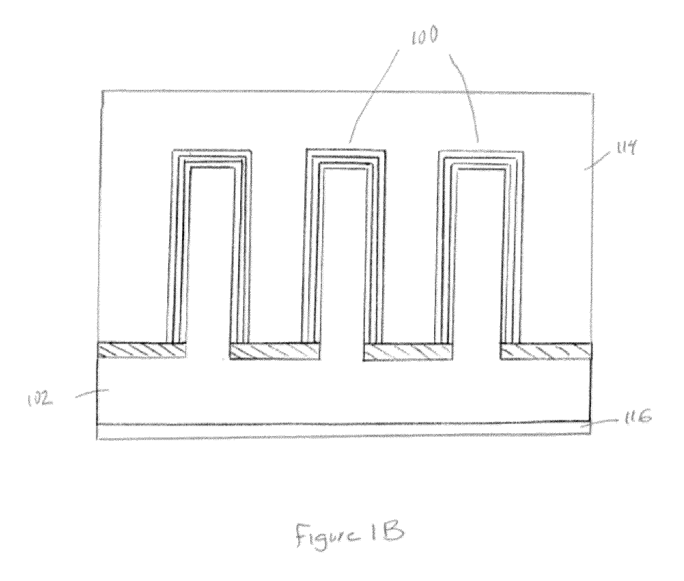

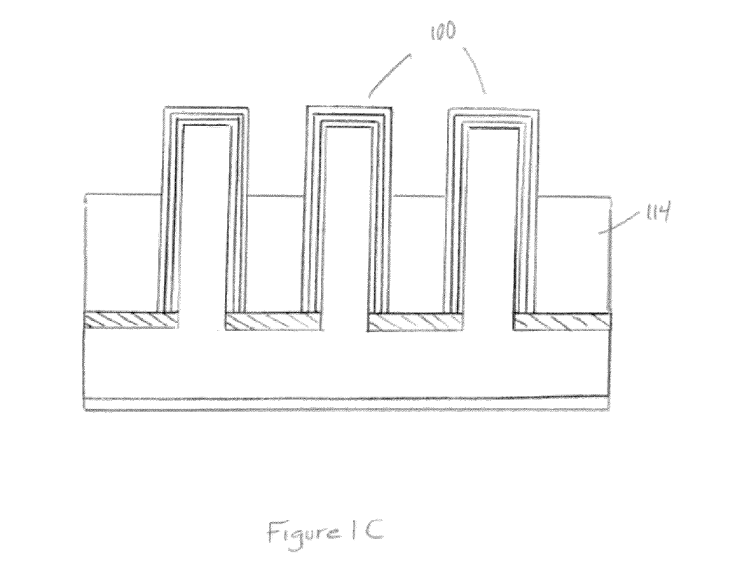

FIG. 1A through FIG. 1D display a fabrication method of a NP-based PV device, according to an embodiment of this disclosure.

Referring to FIG. 1A, an array of core-multishell NPs 100 are grown on a top surface of a substrate 102 by way of selective-area metal organic chemical vapor deposition, in the substantial absence of a metal catalyst that can adversely affect the device performance. In the illustrated embodiment, n-doped GaAs cores 104 are first formed on the substrate 102, which includes a patterned masking layer 106 to provide exposed regions for epitaxial growth of the n-doped GaAs cores 104. Secondly, intrinsic GaAs shells 108 are formed so as to conformally cover respective ones of the n-doped GaAs cores 104, followed by forming p-doped GaAs shells 110 conformally covering respective ones of the intrinsic GaAs shells 108. A thickness of the intrinsic GaAs shells 108 can be in the range of about 1 nm to about 100 nm, such as from about 1 nm to about 50 nm or from about 1 nm to about 30 nm, and a thickness of the p-doped GaAs shells 110 can be in the range of about 1 nm to about 100 nm, such as from about 20 nm to about 80 nm or from about 20 nm to about 60 nm. Next, indium gallium phosphide (InGaP) passivating shells 112 are formed so as to conformally cover respective ones of the p-doped GaAs shells 110. A thickness of the InGaP passivating shells 112 can be in the range of about 1 nm to about 100 nm, such as from about 1 nm to about 30 nm or from about 1 nm to about 10 nm. It will be understood that InGaP sometimes can be represented as InₓGa₁₋ₓP, where x is at least about 0.01 or at least about 0.02 and up to about 0.5 or more.

For each of the NPs 100, the sequence (along a radial direction extending away from a center axis of the NP 100) of the n-doped GaAs core 104, the intrinsic GaAs shell 108, the p-doped GaAs shell 110, and the InGaP shell 112 forms a radial p-i-n junction that is passivated by the InGaP shell 112 to mitigate against surface recombination. Radial p-n junctions and axial p-i-n and p-n junctions are also contemplated for other embodiments. Although the GaAs-based NPs 100 are disclosed for the illustrated embodiment, NPs formed of other semiconductors are also contemplated, such as other III-V semiconductors, Group IV elemental semiconductors, Group IV compound semiconductors, Group VI elemental semiconductors, II-VI semiconductors, I-VII semiconductors, IV-VI semiconductors, V-VI semiconductors, and II-V semiconductors, among others. Also, another semiconductor or other passivating material can be used in place of, or in combination with, InGaP, such as another semiconductor having a bandgap energy higher than that of GaAs (or other semiconductor forming the active volume of the NPs 100).

Still referring to FIG. 1A, each of the NPs 100 can have a lateral dimension D (e.g., a width or a diameter along the radial direction) in the range of about 50 nm to about 950 nm, such as from about 100 nm to about 700 nm, from about 100 nm to about 500 nm, or from about 100 nm to about 400 nm, a longitudinal dimension H (e.g., a height or a length along an axial direction) in the range of about 1 μm to about 15 μm, such as from about 1 μm to about 10 μm, from about 1 μm to about 5 μm, or from about 1 μm to about 2 μm, and an aspect ratio of about 2 or greater, such as about 3 or greater, about 4 or greater, or about 5 or greater, and up to about 10 or greater or up to about 50 or greater. In the illustrated embodiment, the lateral dimension D can be uniform along the axial direction (e.g., along the entire longitudinal dimension H) to within ±30% of an average value along the axial direction, such as to within ±25%, ±20%, ±15%, ±10%, ±5%, or is otherwise substantially uniform along the axial direction. A cross-sectional profile or shape of each of the NPs 100 (e.g., as viewed from the top) can be substantially circular or polygonal, such as hexagonally-faceted, square-faceted, rectangular-faceted, or triangularly-faceted, although non-polygonal shapes are also contemplated. The NPs 100 can be arranged in a substantially periodic pattern, such as a square tiling pattern, a triangular tiling pattern, a rectangular tiling pattern, or a hexagonal tiling pattern, with a pitch P between center axes of nearest-neighbor ones of the NP 100 in the range of about 100 nm to about 1.9 μm, such as from about 200 nm to about 1.4 μm, from about 200 nm to about 1 μm, or from about 200 nm to about 800 nm. To enhance light absorption in the periodically arranged NPs 100, a ratio of D to P can be in the range of about 1/10 to about 9/10, such as from about 1/10 to about 4/5, from about 1/10 to about 7/10, from about 1/5 to about 3/5, or from about 2/5 to about 3/5.

Next, referring to FIG. 1B, a bottom ohmic contact or electrode 116 is formed on a bottom surface of the substrate 102 by applying or depositing a conducting material, such as a metal by electron-beam evaporation and annealing. Also, the array of NPs 100 are planarized by applying or depositing an insulating material 114, such as a polymer resin or a ceramic such as a spin-on-glass. After curing, the insulating material 114 is etched back to partly expose the NPs 100, specifically by exposing top portions or tips of the NPs 100, while remaining bottom portions of the NPs 100 are covered by the insulating material 114 as displayed in FIG. 1C. The etch-back operation can be carried out by, for example, dry etching (e.g., reactive ion) or wet etching.

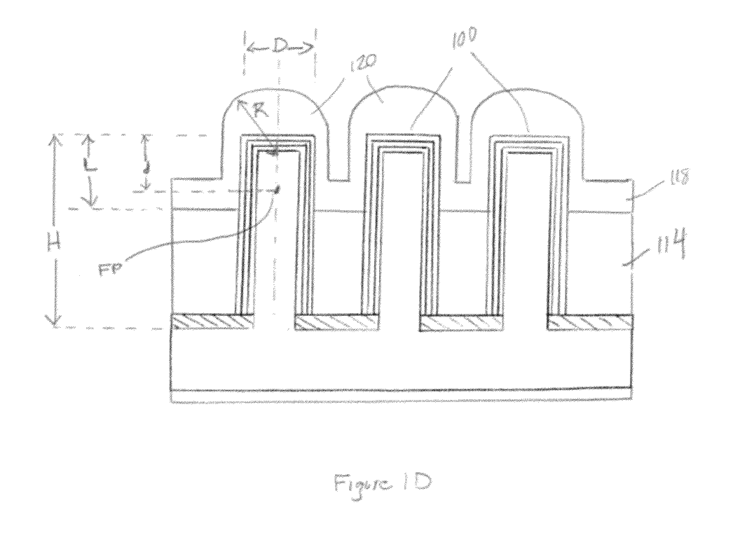

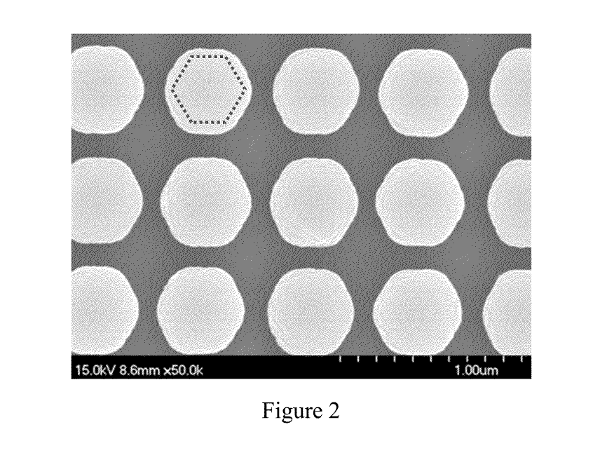

Turning next to FIG. 1D, a top transparent electrode 118 is formed so as to conformally cover exposed tips of the NPs 100, such as by applying or depositing a conformal layer of a TCO using, for example, sputtering, planetary thermal evaporation, spray pyrolysis, or pulsed laser deposition. The top transparent electrode 118 performs dual-functions of an optical concentrator and an ohmic contact, and includes convex or dome-shaped regions 120. Each dome-shaped region 120 is substantially self-aligned with a respective one of the NPs 100, and acts as a subwavelength nanolens that concentrates and augments a photon flux within an active NP volume. FIG. 2 displays a top image of an array of nanolenses conformally covering and aligned with an array of NPs, according to an embodiment of this disclosure. As displayed, each of the nanolenses at least partly take on a hexagonal-faceted shape of the NPs, with a high or substantial uniformity in shape and aspect ratio across the array of the nanolenses.

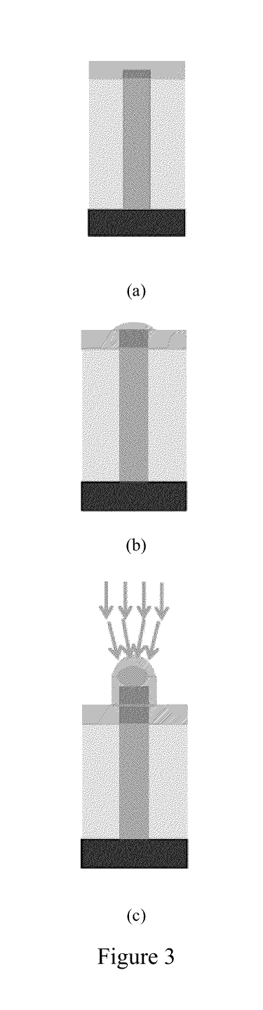

Turning back to FIG. 1D, a radius of curvature R of each dome-shaped region 120 can be tuned by an extent L of the exposed tips of the NPs 100 after the etch-back operation. Shallow exposure can translate into a planar TCO morphology or a morphology with small undulations (see FIG. 3(a)), whereas greater exposures can form self-aligned nanolenses on top of the NPs 100 (see FIGS. 3(b) and (c)). Referring to FIG. 1D, enhanced optical concentration effect can be attained by tuning the radius of curvature R from a planar morphology towards smaller values, such as up to about 1 μm, up to about 950 nm, up to about 900 nm, up to about 800 nm, up to about 700 nm, up to about 600 nm, up to about 500 nm, or up to about 400 nm, and down to about 200 nm, down to about 150 nm, or less. A ratio of the radius of curvature R to the lateral dimension D of the NPs 100 can be up to about 3/1, up to about 2.5/1, up to about 2/1, up to about 1.8/1, up to about 1.6/1, up to about 1.4/1, up to about 1.2/1, or up to about 1/1, and down to about 0.8/1, down to about 0.5/1, or less. Such tuning of the radius of curvature R can be attained by controlling the etch-back operation to yield the extent L of the exposed tips of the NPs 100 to be at least about 50 nm, at least about 100 nm, at least about 150 nm, at least about 200 nm, at least about 250 nm, at least about 300 nm, or at least about 350 nm, and up to about 1 μm, up to about 2 μm, or more. A ratio of the extent L of the exposed tips to the longitudinal dimension H of the NPs 100 can be at least about 1/20, at least about 1/15, at least about 1/10, at least about 1/5, or at least about 3/10, and up to about 2/5, up to about 1/2, or more. A focal point FP of each dome-shaped region 120 can be similarly tuned by the etch-back operation, and also can be wavelength-dependent and material-dependent according to an absorption length within an active NP volume. To mitigate against surface recombination, the focal point FP is desirably tuned to a depth d below a top surface of each NP 100 of at least about 10 nm, at least about 50 nm, at least about 100 nm, at least about 150 nm, at least about 200 nm, at least about 250 nm, or at least about 300 nm, and up to about 1 μm, up to about 2 μm, or more. A ratio of the depth d of the focal point FP to the longitudinal dimension H of the NPs 100 can be at least about 1/20, at least about 1/15, at least about 1/10, at least about 1/5, at least about 3/10, at least about 2/5, or at least about 1/2, and up to about 3/5, up to about 4/5, or more.

The resulting NP-based PV device can exhibit a number of improved performance characteristics, such as one or more of the following: (1) a photon-to-electron power conversion efficiency (PCE) of at least about 3.5% under AM1.5G illumination, such as at least about 4%, at least about 4.5%, at least about 5%, at least about 5.5%, at least about 6%, at least about 6.5%, at least about 7%, and up to about 7.5%, up to about 7.8%, or more; (2) an open-circuit voltage (V_{OC}) of at least about 0.45 V under AM1.5G illumination, such as at least about 0.5 V, at least about 0.53 V, at least about 0.55 V, or at least about 0.57 V, and up to about 0.6 V, up to about 0.63 V, or more; (3) a short-circuit photocurrent density (J_{SC}) of at least about 16.3 mA/cm² under AM1.5G illumination, such as at least about 16.5 mA/cm², at least about 16.7 mA/cm², at least about 17 mA/cm², at least about 17.3 mA/cm², at least about 17.5 mA/cm², at least about 17.7 mA/cm², at least about 18 mA/cm², at least about 18.3 mA/cm², at least about 18.5 mA/cm², at least about 18.7 mA/cm², or at least about 18.9 mA/cm², and up to about 19.3 mA/cm², up to about 19.5 mA/cm², or more; (4) a fill factor (FF) of at least about 60% under AM1.5G illumination, such as at least about 63%, at least about 65%, at least about 67%, or at least about 69%, and up to about 73%, up to about 75%, or more; and (5) an average external quantum efficiency (EQE) of at least about 55% over a range of wavelengths from 400 nm to 950 nm, such as at least about 56%, at least about 57%, at least about 58%, at least about 59%, at least about 60%, or at least about 61%, and up to about 65%, up to about 70%, or more.

### Example

The following example describes specific aspects of some embodiments of this disclosure to illustrate and provide a description for those of ordinary skill in the art. The example should not be construed as limiting this disclosure, as the example merely provides specific methodology useful in understanding and practicing some embodiments of this disclosure.

### Direct-Bandgap Epitaxial Core-Multishell Nanopillar PV Devices Featuring Subwavelength Optical Concentrators

In this example, finite-difference time domain (FDTD) simulations are correlated with current-voltage (J-V) and external quantum efficiency (EQE) experimental data of GaAs p-i-n core-multishell NP solar cells capped with InGaP window shells, with measured AM1.5G power conversion efficiency (PCE) of about 7.43%. The analysis highlights a residual surface state density after epitaxial passivation and an appreciable optical focusing effect arising from a dome-shaped indium tin oxide (ITO) layer that intensifies and concentrates the optical field within the NPs. Optically, the dome-shaped ITO layer functions as a two-dimensional periodic array of subwavelength lenses that focus the local density of optical states within the NP active volume. At short wavelengths, the lens-like behavior is localized at the NP tips whereas at longer wavelengths the light field penetrates deeper, yet confined into the NPs. The solar cells provide a path to high-efficiency NP-based PVs by synergistically controlling the heteroepitaxy and light management of the final structure.

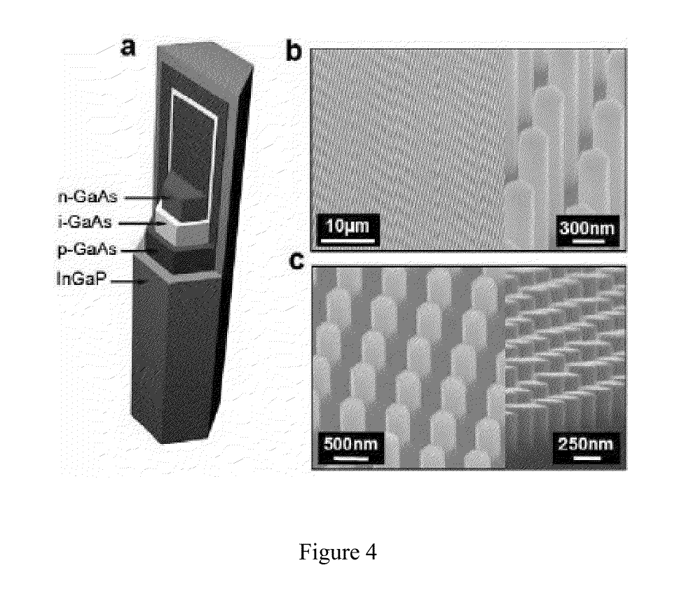

The GaAs NP solar cells included a core-multishell structure as shown in the schematic of FIG. 4a. The NPs are grown by way of selective-area metal organic chemical vapor deposition, without any metal catalyst to foster the synthesis that could affect the device performance. The masking and growth conditions are similar to those reported in Shapiro et al., “InGaAs heterostructure formation in catalyst-free GaAs nanopillars by selective-area metal-organic vapor phase epitaxy,” Appl. Phys. Lett. 97, 243102-243102-3 (2010), the disclosure of which is incorporated herein by reference in its entirety. In brief, a tin (Sn)-doped GaAs n-core (N_{D} of about 1×10¹⁷ cm⁻³, from planar calibrations) with about 180 nm diameter is first grown on a substrate. Secondly, an about 10 nm thick intrinsic GaAs shell followed by an about 40 nm thick zinc (Zn)-doped GaAs p-shell (N_{A} of about 3×10¹⁸ cm⁻³) are formed. Lastly, an about 5 nm thick InGaP window layer is synthesized to mitigate NP surface recombination. This is carried out by a careful control of the heteroepitaxy in the NP in terms of temperature and flow rates during growth. The final core-multishell NP height and diameter are about 1.3 μm and about 290 nm, respectively. FIG. 4b shows a scanning electron microscopy (SEM) image of a typical array growth. The NPs are hexagonally-faceted, arranged in a square tiling pattern. Ratios of diameter (D) and pitch (P) of about 0.517 are shown to maximize the absorption in periodic GaAs NP arrays; therefore a pitch of about 600 nm is chosen in this example. Subsequent to epitaxy, benzocyclobutene (BCB) is used to planarize the NP array and, after hard curing, etched back to expose about 350 nm tips. FIG. 4c displays the partly-exposed NPs. On the right half of the Figure, a 80 degree-tilted SEM image is provided to illustrate the low variability in height, demonstrating fairly constant growth rates for the NPs across the device.

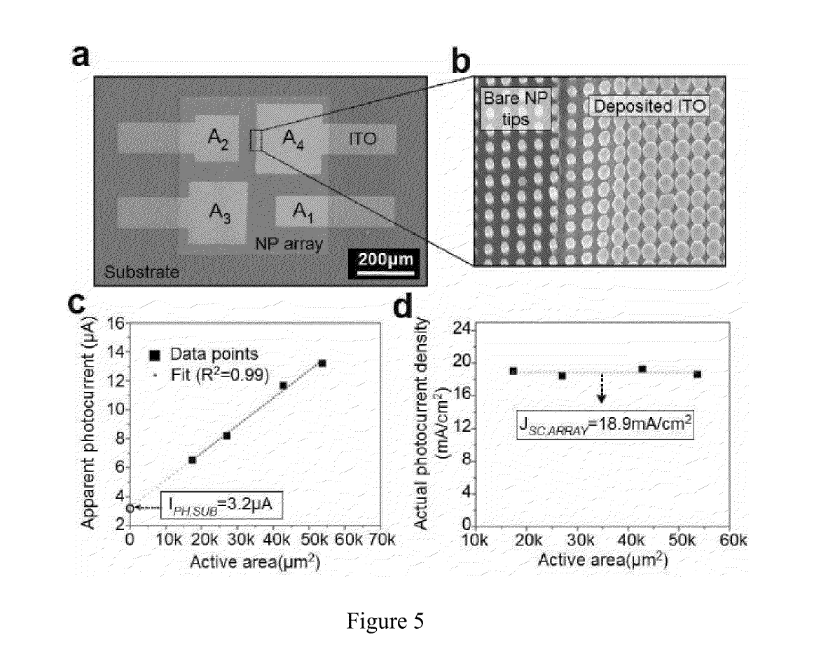

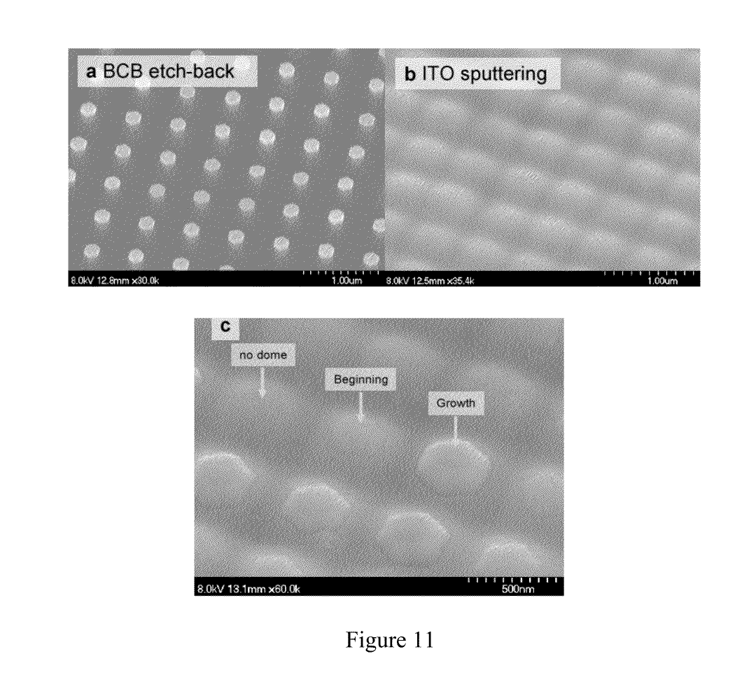

Photocurrent spectroscopy measurements on doped-GaAs homoepitaxial layers have shown photocurrent contributions resulting from illuminating the semiconductor. An estimated minority carrier diffusion length between about 0.4 μm and about 2 μm has been extrapolated for layers at different doping concentrations. Therefore, it desirable to rule out possible photocurrents generated in the substrate (I_{PH,SUB}) that could be recollected by the NP arrays, measuring a higher apparent short-circuit current density (J_{SC,APP}) given by:

$${J}_{SC , APP} = \frac{{I}_{PH , SUB} ( V = 0 ) + {I}_{PH , ARRAY} ( V = 0 )}{Active Array Area}$$

where I_{PH,ARRAY} represents an actual photocurrent output by the NP-array solar cell. In order to separate the two addends, an area-dependent measurement is involved. Each NP-array PV device, in fact, is grown on a diced 1 cm×1 cm n-doped GaAs substrate, where a NP sub-region is specified as an active area. For this reason, an about 0.5 mm×about 0.5 mm active array area is specified. FIG. 5a presents a top-view SEM image where four different transparent electrodes with increasing areas are contacting the NP-array: A1, A2, A3, and A4 correspond to NP-areas of about 14,410, about 27,030, about 42,830, and about 53,700 μm², respectively. The probing pads that extend outside the active regions are electrically isolated from the substrate by the BCB resin. FIG. 5b displays a contact boundary between the bare NP tips after the planarization process and the sputtered contact that forms a dome-shaped ITO transparent electrode. The morphology of the ITO layer is dependent on the height of etched back NP tip as presented in FIG. 11. A thin titanium interlayer is found to improve the ohmic behavior at the ITO/p-GaAs interface after rapid thermal annealing. FIG. 5c plots the apparent photocurrent as a function of increasing areas. The measurements reveal a linear dependence with respect to the number of NPs contacted which are indeed responsible for the collective PV response of the devices. Nonetheless, the linear regression intercepts the y-axis at I_{PH,SUB}=about 3.2 μA for a zero projected active area. This result quantifies a parasitic photocurrent presumably generated by the semiconductor substrate under AM1.5G illumination. The actual photocurrent values delivered by the NP solar cells can be extrapolated by rigidly translating downwards the linear curve to intercept the origin. Subsequent to the correction for the substrate baseline, an area-independent plot of the actual photocurrent density can be formalized as presented in FIG. 5d

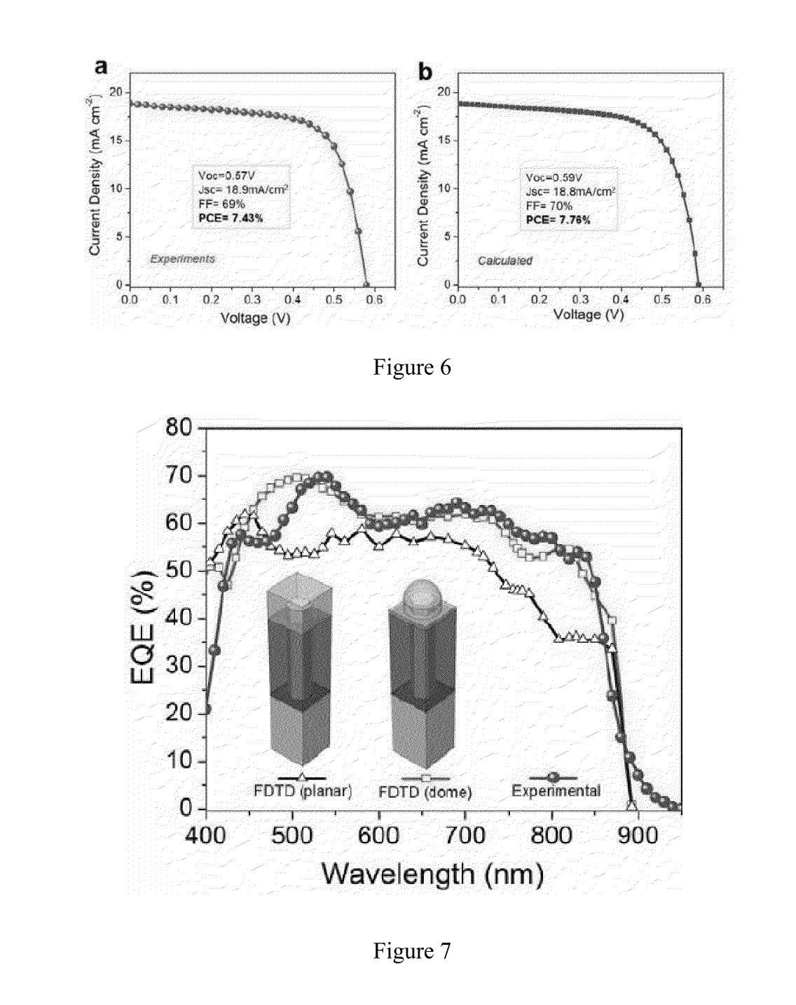

Core-multishell NP-array photovoltaic devices are tested both under dark and under AM1.5G conditions. In the dark, an ideality factor of the GaAs p-i-n NP-array is about 1.86, whereas a rectification ratio at ±1 V is >about 10⁵. Reverse-bias leakage currents of about 48 nA at −1 V indicate a high quality material, where the detrimental effect of surface states is moderated by capping the active region with a thin, lattice-matched, high bandgap InGaP shell. Under illumination, open-circuit voltages (V_{oc}) of about 0.57 V, short-circuit photocurrent densities (J_{sc}) of about 18.9 mA/cm² with fill factors (FF) up to about 69% are observed as shown in the J-V characteristic of FIG. 6a. The resulting power conversion efficiency (PCE) η of about 7.43% represents a considerable improvement with respect to other designs for GaAs NP-array PV devices. The measured PCE considers the sole photocurrent contribution generated in the NP-array. Other GaAs-based epitaxial NW solar cells have been affected by low V_{oc} values ranging from 0.2 V to 0.24 V, without the adoption of a passivation scheme and depending on different growth methods. Part of the reason is related to the large surface-to-volume ratio involved in NP-based PV devices. Since the active junction increases as well as surface/interface recombination rates, InGaP window layers are demonstrated to reduce the surface recombination in GaAs solar cells. To gain insight on electronic transport under AM1.5G, FDTD and electrical simulations are carried out using Sentaurus TCAD software suite. The FDTD method has been widely adopted in optoelectronic modeling of NPs, allowing the analysis of subwavelength light trapping mechanisms in a wave optics framework.

FIG. 6b displays calculated J-V characteristics under light, introducing a residual surface state density Nₛ=1×10¹⁰ eV⁻¹ cm⁻². One major V_{oc} improvement compared to other NP designs can be attributed to both the epitaxial windows as well as the p-i-n junction design. Of note, p-i-n junction schemes demonstrate higher V_{oc} compared to p-n core-shell structures due to a decreased dark saturation current, for NW diameters as low as about 200 nm. Nonetheless, incomplete Fermi level unpinning at the surface is responsible for a lower V_{oc} with respect to planar PV, attributed in part to a non-ideal passivation. This leads to a remainder surface recombination velocity S_{PASS} of about 10⁴ cm/s after passivation. Additionally, a complete array of NPs offers a route to large area integrations; however, it is much more sensitive to variations compared to single-NW photovoltaics: defective NPs across the whole array can directly reduce the device shunt resistance. The V_{oc} of NP solar cells is an ensemble measurement of millions of miniaturized junctions connected in parallel between anode and cathode, and slight variations in electrical properties of each single NP (e.g., shunt resistance, built-in electric field, and ideality factor) may affect the overall J-V characteristics.

FIG. 7 displays the EQE of the corresponding photovoltaic NP devices. The experimental spectral data (circular dots), taken from 400 nm to 950 nm wavelength, shows maximum EQE values of about 70%, with an average magnitude EQE_{AVE}>about 60%. Several peaks can be noticed at different wavelengths which can be attributed to confinement/localization of guided modes within the NP-array. As presented in FIG. 5b, the overlaid ITO electrode assumes a dome-shaped morphology on top of the NPs due to the conformal type of deposition. The particularly rounded geometry occurs from the high nearest-neighbor interaction of the sputtering plasma among NPs in the highly-packed array. The self-constituted nanostructured ITO layer has excellent light trapping capabilities due to its nanophotonic effects. Nonetheless, a high-efficiency PV device is characterized by enhanced solar absorption but also a collection of photocarriers which specifies coupling of both optical and electrical modeling. In order to calculate an optical generation rate Gₚₕ, the Poynting vector S is specified in the form of:

$${G}_{p h} = \frac{\vert \vec{∇} \cdot \vec{S} \vert}{2 ℏ ω} = \frac{{ɛ}^{″} {\vert \vec{E} \vert}^{2}}{2 ℏ}$$

where ω is the frequency of the incident light, h is the reduced Planck's contact, E is the electric field intensity at each grid point, and ε″ is the imaginary part of the permittivity. For the electrical modeling, optical generation profiles are first interpolated automatically to the finite-element mesh of the NPs, and then a coupled set of Poisson Equation and carrier continuity equations are solved for each meshing point in order to compute the photocurrent at each wavelength.

The resulting simulations (squares and triangles) are presented in FIG. 7 and directly compared to the experimental data (circular dots). The EQE curves are found to be in good agreement within most of the wavelength range of interest (here, 400 nm to 900 nm). The two peaks located at λ=about 520 nm and λ=about 810 nm are caused by Mie resonance that leads to a highly effective coupling of incident light into the dome-shape ITO layer that through a leaky channel is funneled into the NPs. Conversely, the simulated EQE curve with planar ITO layer shows no significant peaks at the aforementioned wavelengths, since the planar ITO layer functions solely as a common anti-reflective coating (ARC), whereas the dome-shaped ITO layer creates a graded effective refractive index profile between air and the NPs, attenuating the surface reflection in a broad range of spectrum. In the long wavelength range (λ>700 nm), the EQE values of the structure with planar ITO layer drops dramatically as the incident light is less confined inside the NPs and more dissipated to the substrate with the absence of the dome-shaped ITO layer.

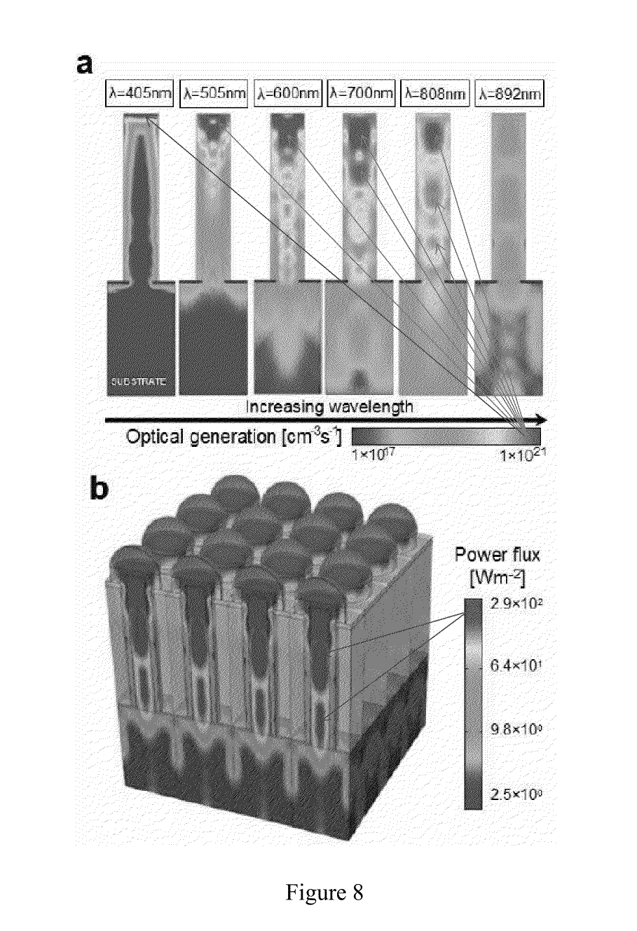

By accurately reproducing in the FDTD simulations both magnitudes and wavelengths of the measured EQE peaks, it is possible to consolidate a clear optical spectral analysis of integrated NP PV devices. FIG. 8a displays vertical cross-sections of optical generation profiles through the center of a NP. Six different wavelengths are outlined: 405 nm, 505 nm, 600 nm, 700 nm, 808 nm, and 892 nm. At λ=405 nm where the absorption length of GaAs is fairly short, the majority of photocarriers are generated at the surface of the NP, being the most sensitive to surface recombination and thus resulting in a relatively lower measured EQE. At longer wavelengths, the optical field is penetrating deeper into the internal part of the NP, generating electron-hole pairs more evenly distributed along the core-multishell structure. This, is demonstrated by higher EQE values. Since the NP size is comparable to the wavelength, a higher portion of the carriers is generated where the constructive interference of light takes place. The nanostructured ITO efficiently concentrates the light from the top portion of the NP. As a consequence, the photogeneration rate is greatly increased. In other words, the dome-shaped ITO acts as a nanolens layer on top of the NP array, where the effective focal point is wavelength-dependent: the high optical generation region (lobes highlighted by arrows) originating from the top of the NP migrates into the NP body for increasing wavelengths, as revealed by FIG. 8a. Notably, these results demonstrate the confinement of light into nanoscale volumes, with minimal photogeneration located at the substrate. Reducing the amount of the active absorber represents a particular advantage of nanostructures, allowing practical low-cost PV devices. This demonstrates the capability to recycle the substrate for consecutive growths, further reducing production costs. FIG. 8b exhibits a three-dimensional power flux density map of a 4-by-4 array of NPs under AM1.5G, with the front row cut away from the middle of the structure. The Figure confirms the coupling of incident light into a two-dimensional array of nanolenses and subsequently into the whole NP array. A large portion of the power density is waveguided within the NP, leading to an increased local density of optical states. The map is calculated considering a solar spectrum-weighted incident power, where both subwavelength effects from an infinitely periodic NP array and a dome-shaped ITO array are synergistically modeled.

In conclusion, this example presents 7.43%-AM1.5G efficiencies for periodic arrays of GaAs core-multishell NP solar cells and correlates J-V and EQE measurements with FDTD simulations for a full-wave optoelectronic analysis of the devices. Area-dependent photocurrent characterization quantifies substrate current contributions that could lead to an overestimation of short-circuit current densities in NP-based solar cells. J-V calculations highlight a residual surface state density Nₛ=1×10¹⁰ eV⁻¹ cm⁻² after epitaxial passivation. Full-wave calculations fit with good fidelity the EQE experimental data and allow to extract realistic photogeneration profiles and delve into the spectral behavior of the fully-integrated NP PV device. High optical absorption arising from the NP matrix is a desirable but not sufficient condition to achieve high-efficiency NP-based PV devices: cohesive optical and electrical investigation of the complete solar cells allows the correlation of theoretical calculations with experimental results. This study demonstrates that epitaxial window layers are desirable to reduce surface recombination and the dome-shape of the nanostructured ITO layer can greatly foster the light coupling within the periodic NP array with respect to flat ARC depositions. The confinement of optical power flux inside the nanostructures effectively reduces the amount of active absorber with respect to thin-film architectures, allowing substrate recycling for practical low-cost PV devices.

Methods

NP Growth.

The growth of the GaAs NP arrays is achieved using a vertical-flow metal organic chemical vapor deposition chamber. N-doped GaAs cores are grown at about 730° C. for about 15 mins, the intrinsic GaAs regions are synthesized at about 600° C. for about 1 min, and the p-doped shells are grown for about 5 mins at about 600° C. Lastly, InGaP window layer is grown for about 45 sec at about 600° C. Di-methyl-zinc and tetra-ethyl-tin are used as p- and n-dopant, respectively.

Device Fabrication and Characterization.

After epitaxy, all samples undergo an acetone-methanol-isopropanol rinse for about 1 min. Aqueous solution of ammonium hydroxide (dilution ratio of about 30:1, H₂O:NH₄OH) is utilized to remove any native oxide at room temperature for about 30 s. Bottom ohmic contacts (Ge(about 5 nm)/Ni(about 10 nm)/Ge(about 15 nm)/Au(about 200 nm)) are deposited by electron-beam evaporation and annealed rapidly at about 380° C. for about 1 min. Benzocyclobutene (BCB, Dow Chemical) is spin-coated, hard-cured, and etched back by reactive-ion etching (O₂/CF₄) to expose the top portion of the NPs. Photolithography is used to pattern the area-dependent contacts with increasing areas. Transparent contacts or electrodes are deposited by radio-frequency sputtering at about 300 W for about 40 mins, in an Ar/O₂ environment. J-V characteristics are acquired using a source meter (Keithley 2400). AM1.5 global (AM1.5G) illumination is achieved with a solar simulator equipped with a 300 W xenon-bulb (Newport 67005), a diffuser, and AM1.5G filter to smoothen any lamp peak. The AM1.5G illumination spot diameter is about 33 mm on the device positioning stage. The EQE spectra are recorded using a manufactured EQE setup (Newport 74125), which includes a monochromator, lock-in amplifier, and calibrated silicon photodiode. A 100 mm-focal length objective lens is used to concentrate the spot size.

FDTD Simulations.

Optoelectronic simulations are calculated using FDTD methods (Sentaurus TCA, Synopsys Inc.). For the optical modeling, Sentaurus Electromagnetic Wave Solver (EMW) is used to perform FDTD calculations. Wavelength-dependent optical constants (refractive indices η and extinction coefficients κ) of GaAs and ITO are adopted from previous works, whereas the refractive index of BCB is set constant at η=1.54. To simulate the whole NP array, periodic boundary conditions are set on the side of the as-built structure, while Higdon absorbing boundary conditions are imposed at the top and the bottom of the structure. Normally-incident light is specified with power intensity and wavelength values from a discretized AM 1.5G solar spectrum. The corresponding unpolarized signature is achieved by superimposing the transverse electric (TE) and transverse magnetic (TM) mode contributions. For the electrical modeling, first the optical generation profiles are interpolated automatically to the finite-element mesh of the NPs, and then a coupled equation set of Poisson equation and carrier continuity equations are solved for each mesh point with specific boundary conditions in order to obtain the photocurrent at each wavelength. Shockley-Read-Hall recombination, Auger recombination, and radiative recombination are all considered, while the carrier mobility is set to be doping dependent. Ideal ohmic contacts are specified both at the tip of the nanowire and the bottom of the substrate.

Recombination Model Adopted in FDTD Simulations.

The electrical simulation is run on Sentaurus TCAD, mainly in the Sentaurus Device module. The carrier lifetimes for electrons and holes are set to be 10 ps. The mobility of electrons and holes are μₑ=5,000 cm²/Vs, μₕ=250 cm²/Vs, respectively. Shockley-Read-Hall recombination rate in the NP is calculated based on the formula:

$${R}^{SRH} = \frac{np - {n}_{i , eff}^{2}}{{τ}_{p} ( n + {n}_{1} ) + {τ}_{n} ( p + {p}_{1} )}$$

where n and p are the electron and hole concentrations at a single mesh point and

n₁=n_{i,eff}exp(Eₜᵣₐₚ/kT)

p₁=n_{i,eff}exp(−Eₜᵣₐₚ/kT)

where n_{i,eff} is set to be 1×10⁶ cm⁻³, and Eₜᵣₐₚ=E_{gap}/2. When calculating the surface recombination rate with interface traps, the above equation can be recast as below:

$${R}_{net} = \frac{{N}_{0} {v}_{th}^{n} {v}_{th}^{p} {σ}_{n} {σ}_{p} ( np - {n}_{i , eff}^{2} )}{{v}_{th}^{n} {σ}_{n} ( n + \frac{{n}_{1}}{{g}_{n}} ) + {v}_{th}^{p} {σ}_{p} ( p + \frac{{p}_{1}}{{g}_{p}} )} = \frac{np - {n}_{i , eff}^{2}}{( n + \frac{{n}_{1}}{{g}_{n}} ) / S + ( p + \frac{{p}_{1}}{{g}_{p}} ) / S}$$

where

gₙ=gₚ=1

n₁=N_{C}exp[(Eₜᵣₐₚ−E_{C})/kT]

p₁=Nₚexp[(E_{V}−Eₜᵣₐₚ)/kT]

vₜₕ=vₜₕⁿ=vₜₕ^{p}=1×10⁷ cm/s are the thermal velocities, and σ=σₙ=σₚ=1×10⁻¹³ cm² are the trap cross-sections for both electrons and holes, N₀=1×10¹⁰ eV cm⁻² is the density of the interface traps that locate at the mid-bandgap in this example, S=vₜₕσN₀=1×10⁷×1×10⁻¹³×1×10¹⁰=1×10⁴ cm/s is the surface recombination velocity. Each capture and emission process couples the trap to the reservoir of carriers. Auger recombination is also included in the simulation by implementing the equation below:

R^{A}=(Cₙn+Cₚp)(np−n_{i,eff}²)

where Cₙ and Cₚ are the Auger coefficients and equally set to be 1×10⁻³⁰ cm⁶/s. Since GaAs is a direct-band gap material, radiative recombination should also be considered. In the calculation, radiative recombination rate is computed according to the equation below:

R^{rad}=C(np−n_{i,eff}²)

where the constant C is set to be 2×10¹⁰ cm³/s.

The presence of the surface states on the facets of the NPs, which originate from dangling bonds, creates trapped interface charges. For this reason, the charge-carrying volume does not necessarily equal to the physical volume. Furthermore, interface trap density can effectively pin the Fermi level at the surface, with electrical repercussions for narrow NPs.

J-V Comparison of Simulated Planar ITO and Dome-Shaped ITO.

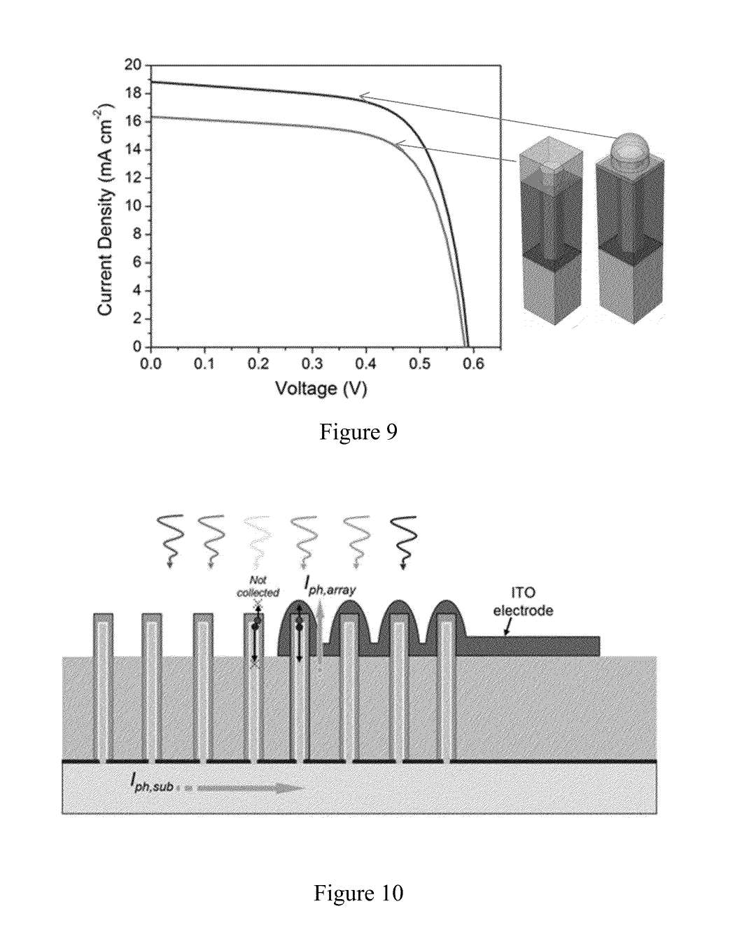

To analyze the effect of ITO nanodomes on top of the periodic NP array in concentrating the photon field, Sentaurus Electromagnetic Wave Solver (full-wave EMW) is used to perform FDTD calculations. The wavelength-dependent optical constants of GaAs and ITO are adopted from previous works, whereas the refractive index of the lossless BCB insulating layer is set to be 1.54 throughout the whole spectrum. To simulate the whole array of GaAs NPs, periodic boundary conditions are set on the side of the as-built structure, while Higdon absorbing boundary condition is set at the top and the bottom of the structure. Optical absorption can be enhanced in arrays of NPs. However, light coupling into the final device structure also can be dictated by the morphology of the transparent electrode (here, ITO). If the optical coupling efficiency between the transparent electrode layer and the incident light field is poor, the resulting power conversion efficiency will be reduced, regardless of whether the NP array acts as an ideal solar absorber. As presented in FIG. 9, depending on the shape of the ITO anode, more light can be effectively funneled into the NP array, therefore resulting into a higher short-circuit photocurrent density with respect to the planar case.

By tuning the morphology of the ITO toward a dome shape, J_{sc} is increased from about 16.2 mA/cm² to about 18.8 mA/cm², resulting into an about 16% improvement. The structure size (e.g., diameter and height) and the electrical properties (e.g., core/shell doping levels) of the NP array are maintained constant for both cases.

Photocurrent Contributions from Area-Dependent Measurements.

As presented in FIG. 5, area-dependent photocurrent measurements are carried out to rule out substrate contributions that could increase the actual photocurrent density to a higher apparent photocurrent density. FIG. 10 graphically outlines different photogenerated carrier pathways. ITO contact pads are specified within the total active area of core-shell NPs. Upon illumination, photocarriers will be produced in all NPs. However, carrier extraction will take place just for the NPs contacted by the transparent electrode. Upon illumination, substrate diffusion currents (I_{PH,SUB}) also can be recollected by the NPs, involving an area-dependent measurement where the total photocurrent is monitored as a function of increasing number of active NP junctions. The layer between the substrate and the ITO layer represents the insulating BCB resin.

Experimental EQE Comparison Between Dome-Shaped and Planar ITO.

Radio-frequency sputtering deposition is applied to NPs where the corresponding tips have been considerably exposed (here, a few hundreds of nm's) with respect to the BCB (Cyclotene) insulating resin, and results in a final conformal deposition of the ITO layer with a dome shape as presented in FIG. 8b. By fabricating devices with a shallow BCB etch-back (FIG. 11a), a dome-less ITO electrode can be achieved (FIG. 11b). The two processing operations are shown in the SEM micrographs of FIG. 11.

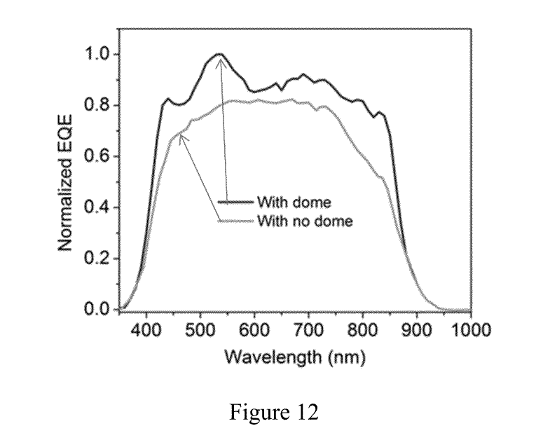

FIG. 11c shows the morphology evolution of a dome: from absence to beginning to actual growth of the dome. The normalized EQE spectra show a higher EQE response for the dome-shaped ITO (FIG. 12). The enhancement stems from the broadband optical focusing effect of dome-shaped ITO compared to a planar deposition sputtering. Efficient coupling of light within the periodic NP array assures a high optical field funneled within the core-shell nanostructures.

While this disclosure has been described with reference to the specific embodiments thereof, it should be understood by those skilled in the art that various changes may be made and equivalents may be substituted without departing from the true spirit and scope of this disclosure as defined by the appended claims. In addition, many modifications may be made to adapt a particular situation, material, composition of matter, method, operation or operations, to the objective, spirit and scope of this disclosure. All such modifications are intended to be within the scope of the claims appended hereto. In particular, while certain methods may have been described with reference to particular operations performed in a particular order, it will be understood that these operations may be combined, sub-divided, or re-ordered to form an equivalent method without departing from the teachings of this disclosure. Accordingly, unless specifically indicated herein, the order and grouping of the operations is not a limitation of this disclosure.

What is claimed is:

1. An optoelectronic device, comprising:
a top transparent electrode;
a bottom electrode spaced apart from the top transparent electrode; and
a plurality of nanopillars arranged between the top transparent electrode and the bottom electrode such that each of the nanopillars includes a top end electrically connected to the top transparent electrode and a bottom end electrically connected to the bottom electrode,
wherein the top transparent electrode is shaped to provide a plurality of optical elements each arranged to couple light into or out of a respective one of the nanopillars.

2. The optoelectronic device of claim 1, wherein at least one of the nanopillars includes an axial junction.

3. The optoelectronic device of claim 2, wherein the axial junction is a p-i-n junction.

4. The optoelectronic device of claim 1, wherein at least one of the nanopillars includes a passivating shell.

5. The optoelectronic device of claim 1, wherein at least one of the nanopillars is a core-multishell nanopillar.

6. The optoelectronic device of claim 1, wherein at least one of the optical elements has a convex shape.

7. The optoelectronic device of claim 1, wherein at least one of the optical elements has a focal point that is within an interior of a respective one of the nanopillars.

8. The optoelectronic device of claim 1, wherein the nanopillars are arranged in an array, and the optical elements are arranged in a corresponding array that is aligned with the array of the nanopillars.

9. A fabrication method of an optoelectronic device, comprising:
providing a substrate and a plurality of nanopillars arranged in an array and each extending from the substrate;
applying an insulating material over the array of the nanopillars;
performing an etch-back of the insulating material to expose tips of the array of the nanopillars; and
depositing a layer of a transparent conducting oxide to conformally cover the exposed tips of the array of the nanopillars,
wherein the layer of the transparent conducting oxide includes convex regions arranged in a corresponding array that is aligned with the array of the nanopillars.

10. The fabrication method of claim 9, wherein depositing the layer of the transparent conducting oxide is carried out by sputtering.

11. The fabrication method of claim 9, wherein performing the etch-back of the insulating material includes controlling an extent of the exposed tips of the array of the nanopillars to yield a desired curvature of the convex regions.

12. The fabrication method of claim 9, wherein performing the etch-back of the insulating material includes controlling an extent of the exposed tips of the array of the nanopillars to yield a desired focal point of the convex regions.
